(19) United States
(12) Patent Application Publication
(10) Pub. No.: US 2025/0183889 A1
(43) Pub. Date: Jun. 5, 2025

(54) Circuit Device

(71) Applicant: SEIKO EPSON CORPORATION, Tokyo (JP)

(72) Inventors: Kazuhiro ADACHI, Suwa (JP); Motoaki NISHIMURA, Chino (JP); Yoshifumi SAKAMOTO, Chino (JP)

(21) Appl. No.: 18/961,685

(22) Filed: Nov. 27, 2024

(30) Foreign Application Priority Data
Nov. 30, 2023 (JP) 2023-202527

(51) Int. Cl. H03K 17/28; G06F 13/40; H03K 19/0175; H04L 12/40

(52) U.S. Cl. CPC H03K 17/28; G06F 13/4072; H03K 19/0175; H04L 12/40; H04L 2012/40215; H04L 2012/4026; H04L 2012/40273

(57) ABSTRACT

A circuit device for driving a differential signal bus includes a high-side transistor between a power supply node and a first output terminal coupled to the differential signal bus, a low-side transistor between a ground node and a second output terminal coupled to the differential signal bus, and a drive circuit output a first drive signal to one of the gate of the high-side transistor and the gate of the low-side transistor and to output a second drive signal to the other of the gate of the high-side transistor and the gate of the low-side transistor. The drive circuit includes a first delay circuit sets a first delay time that is a delay time for the rising edge of the second drive signal, and a second delay circuit sets a second delay time that is a delay time for the falling edge of the second drive signal.

The present application is based on, and claims priority from JP Application Serial Number 2023-202527, filed Nov. 30, 2023, the disclosure of which is hereby incorporated by reference herein in its entirety.

### BACKGROUND

### 1. Technical Field

The present disclosure relates to a circuit device.

### 2. Related Art

Differential signal buses defined in Controller Area Network (CAN), Low-Voltage Differential Signaling (LVDS), FlexRay, and other standards are used in, for example, in-vehicle networks and factory automation (FA) networks. The differential signal bus is a bus that uses a method called the two-wire differential signal method or differential transmission method. CAN is described in JP-A-2015-19219, for example.

For in-vehicle devices and FA devices, it is desirable that the devices be less likely to be affected by noise. Therefore, reducing noise produced by the differential signal bus is important.

### SUMMARY

An aspect of the present disclosure relates to a circuit device for driving a differential signal bus, including a high-side transistor placed between a power supply node and a first output terminal coupled to the differential signal bus, a low-side transistor placed between a ground node and a second output terminal coupled to the differential signal bus, and a drive circuit configured to output a first drive signal to one of a gate of the high-side transistor and a gate of the low-side transistor and to output a second drive signal to another one of the gate of the high-side transistor and the gate of the low-side transistor. The drive circuit includes a first delay circuit configured to set a first delay time that is a delay time for a rising edge of the second drive signal, and a second delay circuit configured to set a second delay time that is a delay time for a falling edge of the second drive signal.

### BRIEF DESCRIPTION OF THE DRAWINGS

FIG. 1 illustrates an exemplary configuration of a circuit device in the present embodiment.

FIG. 2 illustrates exemplary signal waveforms for explaining operations in the present embodiment.

FIG. 3 is a diagram illustrating a CAN bus method.

FIG. 4 is a graph for explaining the CAN bus method.

FIG. 5 illustrates an exemplary detailed configuration of the circuit device in the present embodiment.

FIG. 6 illustrates exemplary signal waveforms for explaining operations in the present embodiment.

FIG. 7 illustrates exemplary signal waveforms in a comparative example.

FIG. 8 illustrates exemplary signal waveforms in the present embodiment.

FIG. 9 illustrates an exemplary configuration of each delay unit.

FIG. 10 is a diagram illustrating a measurement system.

FIG. 11 illustrates exemplary signal waveforms during measurement in the comparative example.

FIG. 12 illustrates exemplary signal waveforms during measurement in the present embodiment.

FIG. 13 depicts simulation results of noise characteristics in the comparative example and in the present embodiment.

FIG. 14 illustrates another exemplary configuration of the circuit device in the present embodiment.

FIG. 15 illustrates exemplary signal waveforms for explaining operations in the other exemplary configuration.

FIG. 16 illustrates an exemplary configuration of a third delay circuit.

FIG. 17 is a diagram for explaining operations of the third delay circuit.

FIG. 18 illustrates another exemplary configuration of the third delay circuit.

FIG. 19 illustrates another exemplary configuration of the circuit device in the present embodiment.

FIG. 20 is a graph for explaining the temperature dependence of electromagnetic interference (EMI) noise.

FIG. 21 illustrates an exemplary configuration of a monitor circuit.

FIG. 22 illustrates exemplary signal waveforms for explaining operations of the monitor circuit.

### DESCRIPTION OF EMBODIMENTS

The present embodiment will be described below. The present embodiment described below does not unduly limit the content of the appended claims. In addition, not all configurations described in the present embodiment are necessarily indispensable constituent elements.

### 1. Circuit Device

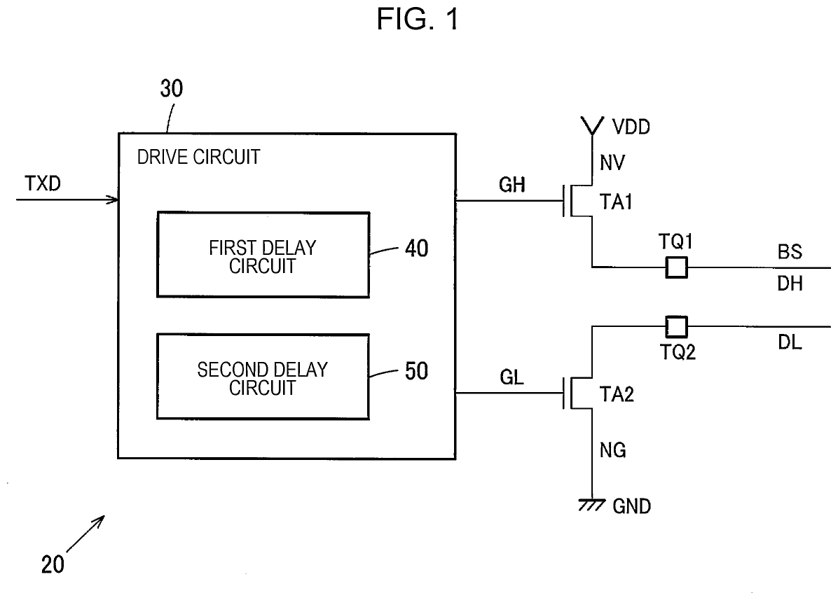

FIG. 1 illustrates an exemplary configuration of a circuit device 20 in the present embodiment. A transceiver using differential signaling to drive a differential signal bus BS is implemented by the circuit device 20. The differential signal bus BS includes a first bus line for a high-side output signal DH and a second bus line for a low-side output signal DL.

As illustrated in FIG. 1, the circuit device 20 in the present embodiment, which drives the differential signal bus BS, includes a high-side transistor TA1, a low-side transistor TA2, and a drive circuit 30. The high-side transistor TA1 is placed between a power supply node NV and a first output terminal TQ1. The low-side transistor TA2 is placed between a ground node NG and a second output terminal TQ2. The first output terminal TQ1 and the second output terminal TQ2 are coupled to the differential signal bus BS. Specifically, the transistor TA1 is configured such that, for example, the source is coupled to the power supply node NV and the drain is coupled to the first output terminal TQ1. The transistor TA2 is configured such that, for example, the source is coupled to the ground node NG and the drain is coupled to the second output terminal TQ2. The node NV is a node to which the power of VDD, a high-potential power supply, is supplied, and the node NG is a node to which the power of the ground, a low-potential power supply, is supplied. In the present embodiment, the ground is appropriately referred to as GND. GND may also be referred to as VSS.

The circuit device 20 in the present embodiment is not limited to the configuration illustrated in FIG. 1 and may be implemented with various modifications, such as omitting some of the components in the configuration, adding other components, and replacing some of the components with others. For instance, a circuit element such as a resistor for setting a voltage level may be placed between the node NV and the transistor TA1, or between the node NG and the transistor TA2. Additionally, a circuit device such as a reverse current protection diode may be placed between the transistor TA1 and the first output terminal TQ1, or between the transistor TA2 and the second output terminal TQ2.

The transistors TA1 and TA2 are transistors for driving the differential signal bus BS. The high-side transistor TA1 drives the first bus line for the output signal DH on the high side of the differential signal bus BS. The first output terminal TQ1 is coupled to the high-side first bus line, and the transistor TA1 drives the first bus line for the output signal DH via the first output terminal TQ1. The low-side transistor TA2 drives the second bus line for the output signal DL on the low side of the differential signal bus BS. The second output terminal TQ2 is coupled to the low-side second bus line, and the transistor TA2 drives the second bus line for the output signal DL via the second output terminal TQ2. The transistor TA1 is, for example, a p-type transistor, and the transistor TA2 is, for example, an n-type transistor. The transistors TA1 and TA2 may be implemented with modifications, such as using n-type transistors as both the transistors TA1 and TA2, or using p-type transistors as both the transistors TA1 and TA2.

The drive circuit 30 outputs a first drive signal to one of the gates of the high-side transistor TA1 and the low-side transistor TA2, and outputs a second drive signal to the other gate. The drive circuit 30 may be referred to as a differential signal transmission circuit. For instance, with reference to FIG. 1, the drive circuit 30 outputs a drive signal GH as the first drive signal to the gate of the high-side transistor TA1, and outputs a drive signal GL as the second drive signal to the gate of the low-side transistor TA2. The drive circuit 30, for example, receives a signal TXD of transmission data to output the drive signals GH and GL. The drive circuit 30, for example, buffers the signal TXD of transmission data to output the drive signals GH and GL. The drive signal GL is, for example, a signal having a level inverted from that of the drive signal GH.

An example will be described below in which the drive signal GH output to the high-side transistor TA1 by the drive circuit 30 is the first drive signal and the drive signal GL output to the low-side transistor TA2 is the second drive signal. However, the drive signal GL output to the low-side transistor TA2 may be the first drive signal and the drive signal GH output to the high-side transistor TA1 may be the second drive signal.

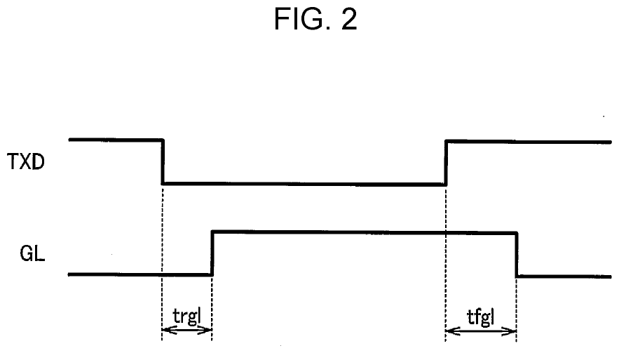

In the present embodiment, the drive circuit 30 includes a first delay circuit 40 and a second delay circuit 50. The first delay circuit 40 sets a first delay time, which is a delay time for the rising edge of the second drive signal, and the second delay circuit 50 sets a second delay time, which is a delay time for the falling edge of the second drive signal. For instance, as depicted in FIG. 2, a delay time trgl for the rising edge of the drive signal GL, which is the second drive signal, is set by the first delay circuit 40, and a delay time tfgl for the falling edge of the drive signal GL, which is the second drive signal, is set by the second delay circuit 50. The delay time trgl is the first delay time, and the delay time tfgl is the second delay time. As described above, the high-side drive signal GH may be the second drive signal, and the delay time for the rising edge and the delay time for the falling edge of the drive signal GH may be set by the first delay circuit 40 and the second delay circuit 50.

As described above, in the present embodiment, the drive circuit 30 outputs the drive signals GH and GL, which are the first drive signal and the second drive signal, to the high-side transistor TA1 and the low-side transistor TA2. Thereby, the differential signal bus BS is driven by the high-side transistor TA1, placed between the power supply node NV and the first output terminal TQ1, and the low-side transistor TA2, placed between the ground node NG and the second output terminal TQ2. Furthermore, the delay time trgl for the rising edge and the delay time tfgl for the falling edge of, for example, the drive signal GL, which is the second drive signal, are independently adjusted by the first delay circuit 40 and the second delay circuit 50 of the drive circuit 30. In this way, proper adjustment of the delay times trgl and tfgl enables the reduction of noise produced by the differential signal bus BS. Even when there are differences in drive capability, parasitic capacitance, and so on between the high-side transistor TA1 and the low-side transistor TA2, noise such as electromagnetic interference (EMI) may be effectively reduced. That is, when the high-side transistor TA1 and the low-side transistor TA2 differ in terms of drive capability and parasitic capacitance, the waveforms of the output signals DH and DL from the first output terminal TQ1 and the second output terminal TQ2 become unbalanced, causing noise in the differential signal bus BS. In this regard, in the present embodiment, the delay time trgl for the rising edge and the delay time tfgl for the falling edge of the drive signal GL may be independently adjusted by the first delay circuit 40 and the second delay circuit 50, enabling the reduction of unbalanced waveforms in the output signals DH and DL to reduce noise produced by the differential signal bus BS. This ensures that devices, such as in-vehicle devices and FA devices, in which the circuit device 20 is integrated, are less likely to be affected by noise.

### 2. Exemplary Detailed Configuration

A specific example of the circuit device 20 in the present embodiment is now described. A specific example of the circuit device 20, where the differential signal bus BS is a CAN bus, is described here; however, the present embodiment is not limited to this. The differential signal bus BS may be a bus that uses another method such as LVDS.

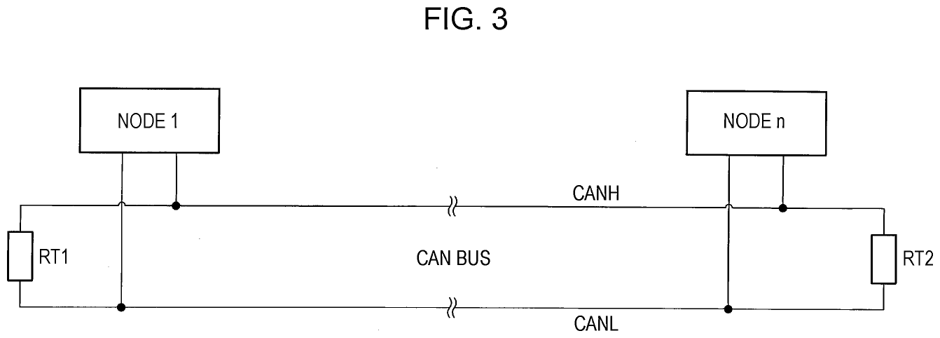

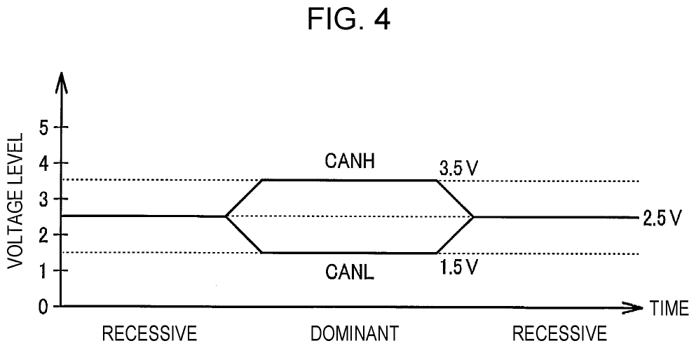

For instance, FIG. 3 is a diagram illustrating CAN, which is used in, for example, in-vehicle devices, and FIG. 4 is a graph depicting the signal waveforms of CAN. As illustrated in FIG. 3, in CAN, a node 1 and a node n, for example, are coupled by a CAN bus. Each of the node 1 and the node n is provided with a transceiver implemented by the circuit device 20 in the present embodiment. The CAN bus, which is the differential signal bus BS, consists of the first bus line for an output signal CANH on the high side and the second bus line for an output signal CANL on the low side. Additionally, a termination resistor RT1 is placed between one end of the first bus line and one end of the second bus line, and a termination resistor RT2 is placed between the other end of the first bus line and the other end of the second bus line. The termination resistors RT1 and RT2 each have a resistance of 120 Q, for example.

In the CAN bus, as depicted in FIG. 4, during the dominant period, for example, both the high-side transistor TA1 and the low-side transistor TA2 turn on. As a result, the high-side output signal CANH is 3.5 V, for example, and the low-side output signal CANL is 1.5 V, for example. In this case, 3.5 V corresponds to the high level of the high-side output signal CANH, and 1.5 V corresponds to the low level of the low-side output signal CANL. Additionally, during the recessive periods, for example, both the high-side transistor TA1 and the low-side transistor TA2 turn off. As a result, both the high-side output signal CANH and the low-side output signal CANL are 2.5 V, which is an intermediate voltage. In this case, 2.5 V corresponds to the low level of the high-side output signal CANH and also corresponds to the high level of the low-side output signal CANL. Thus, in CAN, the sum of the high-side output signal CANH and the low-side output signal CANL is 5 V, remaining constant during both the dominant period and the recessive periods, thereby suppressing EMI noise.

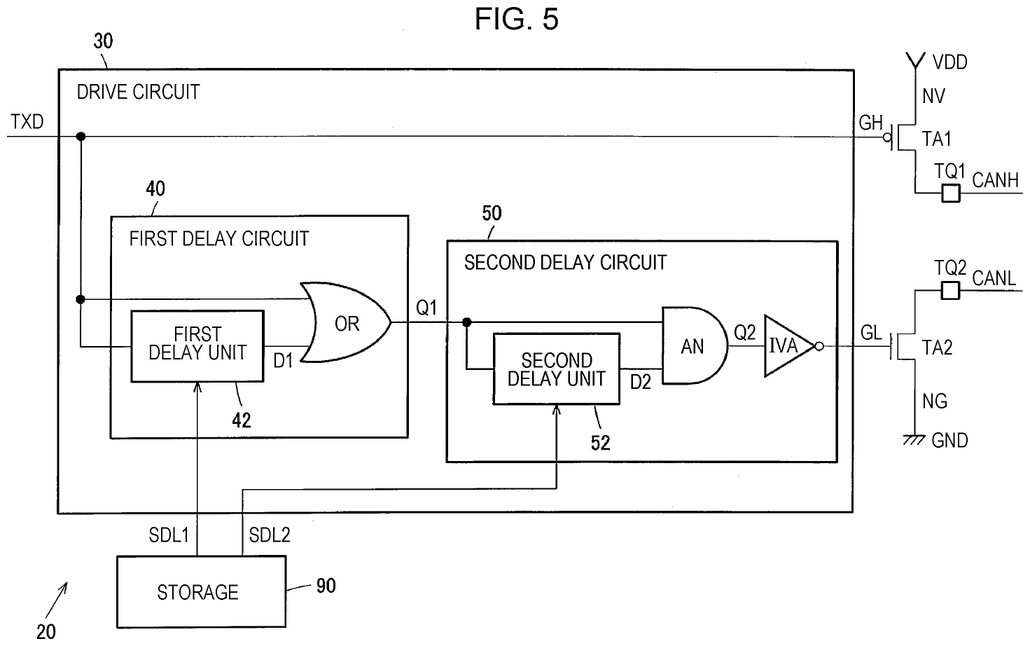

FIG. 5 illustrates an exemplary detailed configuration of the present embodiment. As illustrated in FIG. 5, the circuit device 20 includes the high-side transistor TA1, the low-side transistor TA2, the drive circuit 30, and a storage 90. The circuit device 20 may also include the first output terminal TQ1 and the second output terminal TQ2, which are pads of IC, for example.

The high-side transistor TA1 is a p-type transistor, and the drive signal GH from the drive circuit 30 is input to the gate of the transistor TA1. The low-side transistor TA2 is an n-type transistor, and the drive signal GL from the drive circuit 30 is input to the gate of the transistor TA2.

The drive circuit 30 includes the first delay circuit 40 and the second delay circuit 50. The first delay circuit 40 includes a first delay unit 42 and an OR circuit OR. The first delay unit 42 receives the signal TXD of transmission data, which is an input signal, and outputs a delayed signal D1. The OR circuit OR receives the signal TXD and the signal D1 from the first delay unit 42 and outputs a signal Q1. The second delay circuit 50 includes a second delay unit 52, an AND circuit AN, and an inverter circuit IVA. The second delay unit 52 receives the signal Q1, which is an input signal, from the first delay circuit 40 and outputs a delayed signal D2. The AND circuit AN receives the signal Q1 and the signal D2 from the second delay unit 52 and outputs a signal Q2. The inverter circuit IVA outputs, as the drive signal GL, a signal having a level inverted from that of the signal Q2.

The storage 90 stores delay setting information SDL1 and SDL2. The first delay circuit 40 and the second delay circuit 50 set the delay times of the drive signal GL based on the delay setting information SDL1 and SDL2 stored in the storage 90. Then, the drive signals GH and GL from the drive circuit 30 are input to the gates of the transistors TA1 and TA2, and the output signals CANH and CANL are output from the first and second output terminals TQ1 and TQ2. The output signals CANH and CANL respectively correspond to the output signals DH and DL illustrated in FIG. 1.

The circuit device 20 in the present embodiment is not limited to the configuration illustrated in FIG. 5 and may be implemented with various modifications, such as omitting some of the components, adding other components, and replacing some of the components with others. For instance, in the same manner as mentioned above for the case illustrated in FIG. 1, a reverse current protection diode and a resistor for setting a voltage level may be provided. Additionally, the drive circuit 30 may include a circuit other than the first delay circuit 40 and the second delay circuit 50. Additionally, the drive circuit 30 may output a signal obtained by buffering the signal TXD of transmission data by a buffer circuit (not illustrated), as the drive signal GH, to the gate of the transistor TA1.

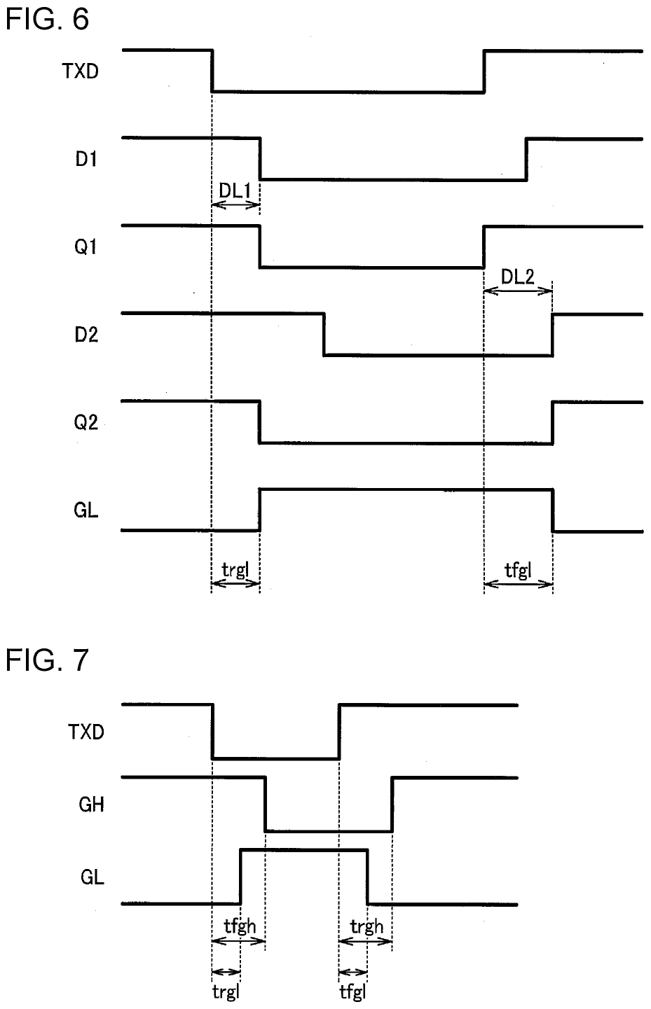

FIG. 6 illustrates exemplary signal waveforms for explaining operations of the circuit device 20 illustrated in FIG. 5. The signal TXD input to the drive circuit 30 is delayed by a delay time DL1 by the first delay unit 42 in the first delay circuit 40, and is then input as the signal D1 to the OR circuit OR. The OR circuit OR then outputs the signal Q1 corresponding to the OR of the signal TXD and the signal D1. For the signal Q1, its falling edge is delayed from the signal TXD by the delay time DL1. The signal Q1 is then delayed by a delay time DL2 by the second delay unit 52 in the second delay circuit 50, and is then input as the signal D2 to the AND circuit AN. The AND circuit AN then outputs a signal Q2 corresponding to the AND of the signal Q1 and the signal D2. For the signal Q2, its falling edge is delayed by the delay time DL1, and its rising edge is delayed by a delay time DL2, from the signal TX. The signal Q2 is then inverted by the inverter circuit IVA to produce the drive signal GL, which is input to the gate of the transistor TA2. This way enables the drive circuit 30 to output the drive signal GL for which the delay time for the rising edge from the signal TXD is set to trgl and for which the delay time for the falling edge from the signal TXD is set to tfgl. In this case, the delay time trgl corresponds to the delay time DL1 in the first delay unit 42, and the delay time tfgl corresponds to the delay time DL2 in the second delay unit 52. Additionally, for the drive signal GL, its rising edge is delayed from one of the falling and rising edges of the signal TXD by the delay time trgl, and its falling edge is delayed from the other edge by the delay time tfgl. Although, in FIG. 6, one edge of the signal TXD is the falling edge and the other edge is the rising edge, the one edge may be the rising edge and the other edge may be the falling edge.

FIG. 7 illustrates exemplary signal waveforms in a comparative example of the present embodiment. In the comparative example, while the first delay circuit 40 and the second delay circuit 50, as in the present embodiment, are not provided, for example, a first buffer circuit inverts and buffers the signal TXD, outputting the buffered signal as the drive signal GL, and a second buffer circuit buffers the drive signal GL, outputting the buffered signal as the drive signal GH. The delay times trgl and tfgl in FIG. 7 correspond to delay times in the first buffer circuit mentioned above, and delay times trgh and tfgh correspond to delay times in the second buffer circuit mentioned above. The delay times trgl, tfgl, trgh, and tfgh are approximately equal and are short delay times of about a few nsec.

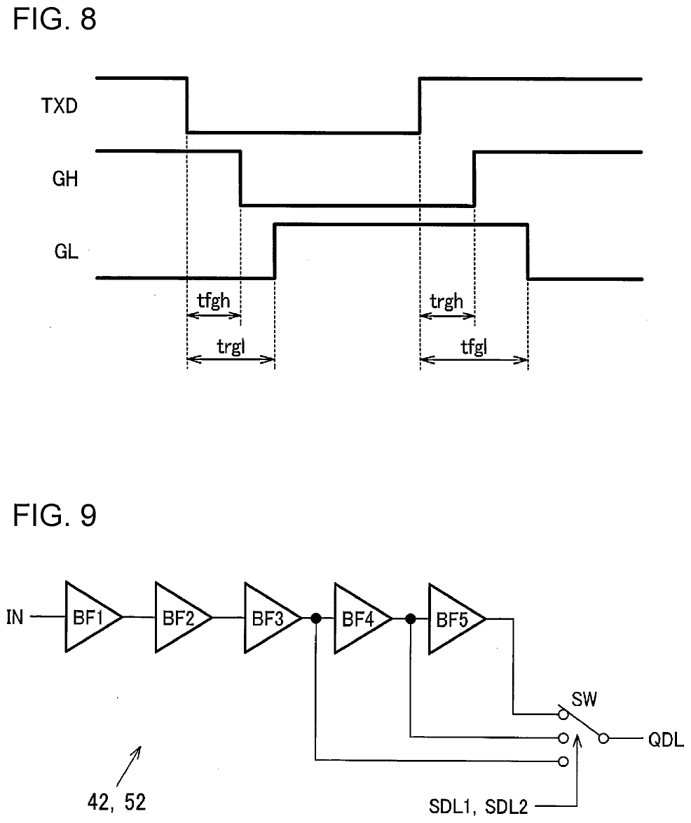

FIG. 8 illustrates exemplary signal waveforms in the present embodiment. In the present embodiment, the first delay circuit 40 and the second delay circuit 50, included in the drive circuit 30, enable individual settings of the delay times trgl and tfgl for the rising and falling edges of the drive signal GL. For instance, the delay time trgl is set by setting the delay time DL1 in the first delay unit 42 of the first delay circuit 40, and the delay time tfgl is set by setting the delay time DL2 in the second delay unit 52 of the second delay circuit 50. Therefore, in contrast to the comparative example illustrated in FIG. 7, the delay times trgl and tfgl may be set to have different lengths. The delay times tigh and trgh for the falling and rising edges of the drive signal GH are approximately equal. For example, when a buffer circuit that buffers the signal TXD to output the drive signal GH is provided, the delay times tigh and trgh are the delay times in the buffer circuit.

FIG. 9 illustrates an exemplary configuration of each of the first delay unit 42 and the second delay unit 52. As illustrated in FIG. 9, each of the first delay unit 42 and the second delay unit 52 includes a plurality of buffer circuits BF1, BF2, BF3, BF4, and BF5 and a switch circuit SW. Each of the buffer circuits BF1 to BF5 receives a signal from the preceding buffer circuit and outputs a signal to the subsequent buffer circuit. Each buffer circuit may be constituted of two stages of inverter circuits, for example.

As illustrated in FIG. 9, the switch circuit SW is controlled based on the delay setting information SDL1 or SDL2 to select an output signal from the buffer circuit BF3, BF4, or BF5 and outputs the selected output signal as a signal QDL. The signal QDL corresponds to the signal D1 or D2 in FIG. 5. For instance, the switch circuit SW in the first delay unit 42 of the first delay circuit 40 is controlled based on the delay setting information SDL1, and the switch circuit SW in the second delay unit 52 of the second delay circuit 50 is controlled based on the delay setting information SDL2.

For instance, when the signal of the delay setting information SDL1 is active, the switch circuit SW in the first delay unit 42 selects an output signal from the buffer circuit BF3 and outputs the selected output signal as the signal QDL (the signal D1). Additionally, when the signal of the delay setting information SDL2 is active, the switch circuit SW in the second delay unit 52 selects an output signal from the buffer circuit BF5 and outputs the selected output signal as the signal QDL (the signal D2). In this way, the delay time DL2 in the second delay unit 52 may be longer than the delay time DL1 in the first delay unit 42. Thereby, the delay time tfgl for the falling edge of the drive signal GL may be longer than the delay time trgl for the rising edge of the drive signal GL.

Alternatively, when the signal of the delay setting information SDL1 is active, the switch circuit SW in the first delay unit 42 selects an output signal from the buffer circuit BF5 and outputs the selected output signal as the signal QDL. Additionally, when the signal of the delay setting information SDL2 is active, the switch circuit SW in the second delay unit 52 selects an output signal from the buffer circuit BF3 and outputs the selected output signal as the signal QDL. In this way, the delay time DL2 in the second delay unit 52 may be shorter than the delay time DL1 in the first delay unit 42. Thereby, the delay time tfgl for the falling edge of the drive signal GL may be shorter than the delay time trgl for the rising edge of the drive signal GL.

Additionally, as illustrated in FIG. 5, the high-side transistor TA1 between the node NV of VDD and the first output terminal TQ1 is a p-type transistor. Additionally, the low-side transistor TA2 between the node NG of GND and the second output terminal TQ2 is an n-type transistor. The transistors TA1 and TA2 are metal-oxide-semiconductor (MOS) transistors, for example. The drive signal GH, which is, for example, the first drive signal, is input to the gate of the high-side transistor TA1, and the drive signal GL, which is, for example, the second drive signal, is input to the gate of the low-side transistor TA2.

As described with reference to FIG. 5, the low-side transistor TA2 is an n-type transistor, and the drive circuit 30 outputs the drive signal GL, which is the second drive signal, to the gate of the n-type transistor TA2. In this way, the first delay circuit 40 and the second delay circuit 50 set the delay time trgl for the rising edge and the delay time tigl for the falling edge of the drive signal GL, enabling the reduction of unbalanced waveforms in the output signals CANH and CANL from the first output terminal TQ1 and the second output terminal TQ2. Therefore, when noise is produced due to unbalanced waveforms in the output signals CANH and CANL, the noise may be effectively reduced by adjusting the delay time trgl for the rising edge and the delay time tigl for the falling edge of the drive signal GL, which is input to the gate of the n-type transistor TA2.

For instance, as illustrated in FIG. 6, the length of the delay time trgl, which is the first delay time, differs from the length of the delay time tfgl, which is the second delay time. That is, the delay time trgl for the rising edge and the delay time tfgl for the falling edge of the drive signal GL, which is the second drive signal, are set to have different lengths. For instance, the behaviors of waveforms of the output signals CANH and CANL, which are respectively output from the first output terminal TQ1 and the second output terminal TQ2 via the transistors TA1 and TA2, differ between a period in which the drive signal GL rises and a period in which the drive signal GL falls. This occurs because, during the period when the transistors TA1 and TA2 turn on, differences in drive capability between the transistors TA1 and TA2 affect the waveforms of the output signals CANH and CANL. Similarly, during the period when the transistors TA1 and TA2 turn off, the differences in the parasitic capacitance between the transistors TA1 and TA2 affect the waveforms of the output signals CANH and CANL. Therefore, different lengths of the delay time trol and the delay time tfgl enable the reduction of unbalanced waveforms in the output signals CANH and CANL to reduce noise resulting from the unbalanced waveforms.

Additionally, as illustrated in FIG. 5, the first delay circuit 40 of the drive circuit 30 sets the delay time trgl for the rising edge of the drive signal GL, as illustrated in FIG. 6, based on the delay setting information SDL1. That is, the delay time DL1 in the first delay unit 42 is set based on the delay setting information SDL1, and, as a result, the delay time trgl is set. The delay setting information SDL1 is first delay setting information, and the delay time trgl is the first delay time. Additionally, the second delay circuit 50 of the drive circuit 30 sets the delay time tfgl for the falling edge of the drive signal GL based on the delay setting information SDL2. That is, the delay time DL2 in the second delay unit 52 is set based on the delay setting information SDL2, and, as a result, the delay time tfgl is set. The delay setting information SDL2 is second delay setting information, and the delay time tfgl is the second delay time. In this way, the first delay circuit 40 may set the delay time trgl as the first delay time of the drive signal GL, which is the second drive signal, based on the delay setting information SDL1 as the first delay setting information. Additionally, the second delay circuit 50 may set the delay time tfgl as the second delay time of the drive signal GL, which is the second drive signal, based on the delay setting information SDL2 as the second delay setting information. Therefore, the delay time trgl for the rising edge of the drive signal GL and the delay time tfgl for the falling edge of the drive signal GL may be set to any values based on the delay setting information SDL1 and SDL2. Thus, when noise is produced due to differences in the drive capability, parasitic capacitance, and so on between the transistors TA1 and TA2, the noise may be effectively reduced by setting the delay setting information SDL1 and SDL2 according to these differences.

Additionally, as illustrated in FIG. 5, the circuit device 20 includes the storage 90 that stores the delay setting information SDL1, which is the first delay setting information, and the delay setting information SDL2, which is the second delay setting information. The storage 90 is, for example, a nonvolatile storage capable of retaining the stored content even when power is not supplied. A nonvolatile memory, a fuse circuit, or the like may be used as the storage 90. Examples of nonvolatile memory include erasable programmable read-only memory (EPROM), electrically erasable programmable read-only memory (EEPROM), and read-only memory (ROM). The fuse circuit is a circuit that stores information in accordance with setting information of a fuse element. For instance, the fuse circuit stores information based on whether a fuse element made of metal or polysilicon is cut or not. When the storage 90 that stores the delay setting information SDL1 and SDL2 in such a manner is provided, the first delay circuit 40 and the second delay circuit 50 may set the delay time trgl for the rising edge and the delay time tgl for the falling edge of the drive signal GL based on the delay setting information SDL1 and SDL2 read from the storage 90. That is, the delay times DL1 and DL2 in the first delay unit 42 and the second delay unit 52 are set based on the delay setting information SDL1 and SDL2, enabling the setting of the delay times trgl and tfgl. Thus, the delay setting information SDL1 and SDL2 having values in accordance with differences in the drive capability, parasitic capacitance, and so on between the transistors TA1 and TA2 are stored in the storage 90, enabling the noise to be effectively reduced. For instance, the delay setting information SDL1 and SDL2 are written to the storage 90 during manufacture or inspection of the circuit device 20 or a device including the circuit device 20.

Additionally, as illustrated in FIG. 5, the first delay circuit 40 includes the first delay unit 42, which delays an input signal to the first delay circuit 40, and the OR circuit OR, which outputs the OR of this input signal and the signal D1 from the first delay unit 42. In FIG. 5, the input signal to the first delay circuit 40 is the signal TXD, which represents transmission data. With the first delay circuit 40 in such a configuration, for example, the signal Q1 corresponding to the OR of the signal D1, which is delayed from an input signal to the first delay circuit 40 by the delay time DL1 by the first delay unit 42, and the input signal may be output from the OR circuit OR. Thus, as illustrated in FIG. 6, for example, the delay time of the drive signal GL may be set by setting the delay time DL1 in the first delay unit 42 of the first delay circuit 40.

Additionally, as illustrated in FIG. 5, the second delay circuit 50 includes the second delay unit 52 that delays an input signal to the second delay circuit 50, and the AND circuit AN that outputs the AND of the input signal to the second delay circuit 50 and the signal D2 from the second delay unit 52. Additionally, as illustrated in FIG. 5, the second delay circuit 50 includes the inverter circuit IVA, which inverts the signal level of the signal Q2 from the AND circuit AN. As illustrated in FIG. 5, the input signal to the second delay circuit 50 is the signal Q1 from the first delay circuit 40. With the second delay circuit 50 in such a configuration, for example, the signal Q2 corresponding to the AND of the signal D2, which is delayed from an input signal to the second delay circuit 50 by the delay time DL2 by the second delay unit 52, and the input signal may be output from the AND circuit AN. Thus, for example, the delay time of the drive signal GL may be set by setting the delay time DL2 in the second delay unit 52 of the second delay circuit 50.

### 3. Measurement of Noise

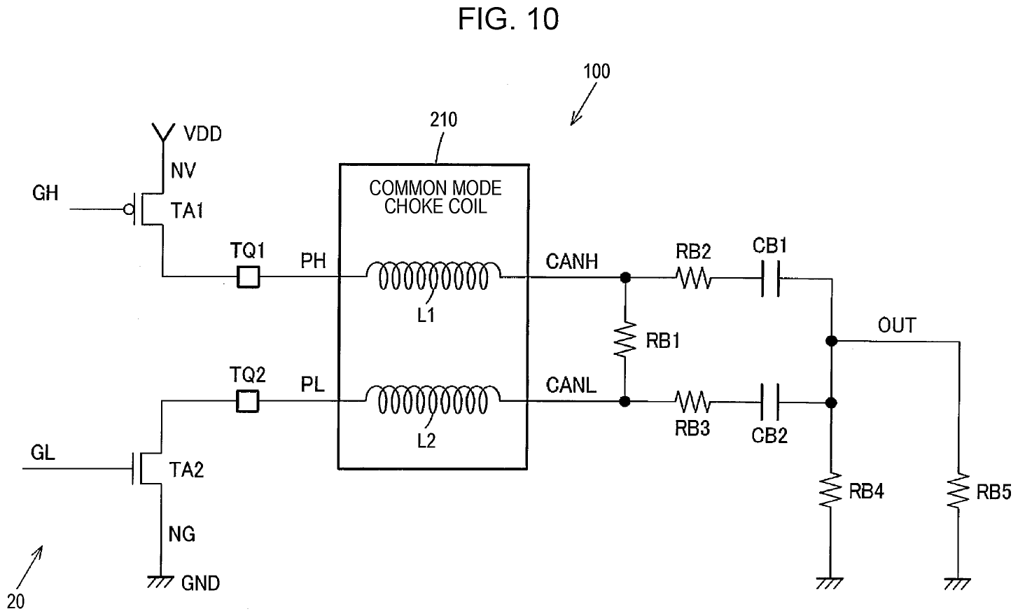

In differential signaling bus methods, such as CAN, requirements regarding noise such as EMI are settled. For instance, FIG. 10 illustrates an exemplary configuration of a measurement system 100 for noise in CAN. The measurement system 100 in FIG. 10 includes a common mode choke coil 210, resistors RB1, RB2, RB3, RB4, and RB5, and capacitors CB1 and CB2. The common mode choke coil 210 includes coils L1 and L2. For the coils L1 and L2 of the common mode choke coil 210, signals PH and PL from the first output terminal TQ1 and the second output terminal TQ2 of the circuit device 20 are input to one end of the coil L1 and one end of the coil L2, and output signals CANH and CANL are output from the other ends, respectively. Due to the common mode choke coil 210, the high-frequency noise of the signals PH and PL is removed. Additionally, the resistors RB1, RB2, and RB3 and the capacitors CB1 and CB2 constitute an adder circuit, from which a signal corresponding to the sum of the output signals CANH and CANL is output as a signal OUT. The resistors RB4 and RB5 correspond to termination resistors.

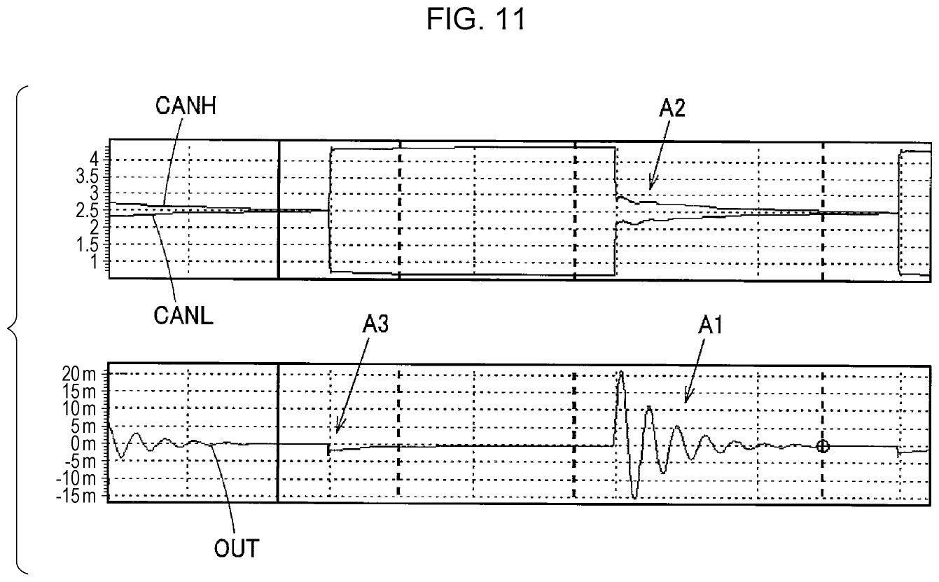

FIG. 11 illustrates exemplary signal waveforms during measurement in the comparative example. In the comparative example, since the first delay circuit 40 and the second delay circuit 50 as in the present embodiment are not provided, noise as indicated by A1 occurs in the signal OUT corresponding to the sum of the output signals CANH and CANL. That is, as described with reference to FIG. 4, in CAN, the sum of the output signals CANH and CANL is 2.5 V, which corresponds to the intermediate voltage, during the dominant period and during the recessive periods, thereby reducing EMI noise. However, in the comparative example in which the delay times are not adjusted by the first delay circuit 40 and the second delay circuit 50, for example, as indicated by A2 of FIG. 11, the waveforms of the output signals CANH and CANL are unbalanced, not symmetric about 2.5 V, for example. Therefore, the signal OUT corresponding to the sum of the output signals CANH and CANL is not at a constant voltage of 2.5 V, resulting in occurrence of noise as indicated by A1, which causes EMI. Although noise also occurs as indicated by A3 of FIG. 11, this noise is smaller than the noise as indicated by A1.

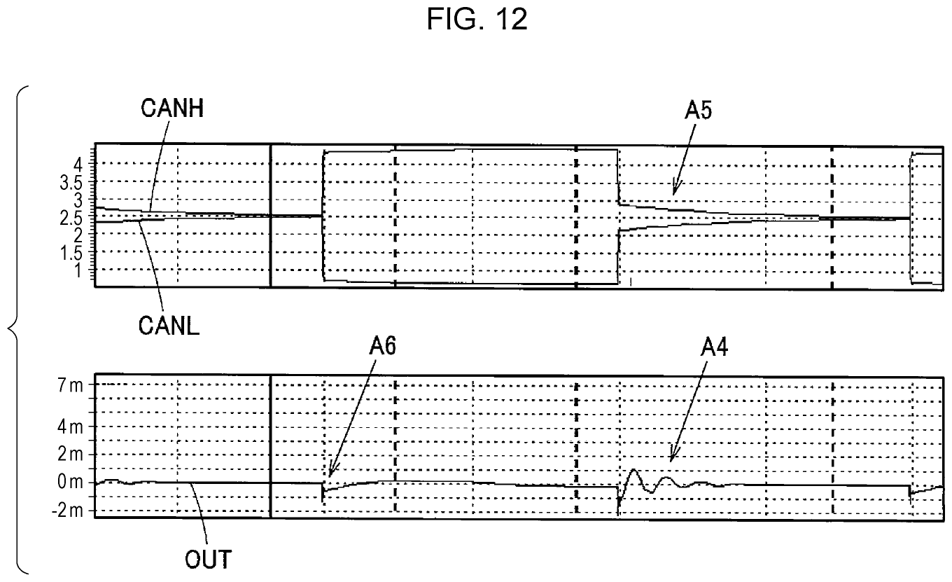

FIG. 12 illustrates exemplary signal waveforms during measurement in the present embodiment. In the present embodiment, since the first delay circuit 40 and the second delay circuit 50 are provided, the delay time trgl for the rising edge and the delay time tigl for the falling edge of the drive signal GL are individually adjusted. Thereby, as indicated by A4 of FIG. 12, noise may be reduced relative to the noise as indicated by A1 of FIG. 11. That is, the delay times trgl and tfgl are adjusted by the first delay circuit 40 and the second delay circuit 50, enabling achievement of the balance between the waveforms of the output signals CANH and CANL so that, for example, as indicated by A5 of FIG. 12, the waveforms are symmetric about 2.5 V, for example. Therefore, as indicated by A4, noise in the signal OUT corresponding to the sum of the output signals CANH and CANL may be reduced relative to the noise as indicated by A1 of FIG. 11. Although noise also occurs as indicated by A6 of FIG. 12, this noise is smaller than the noise as indicated by A4.

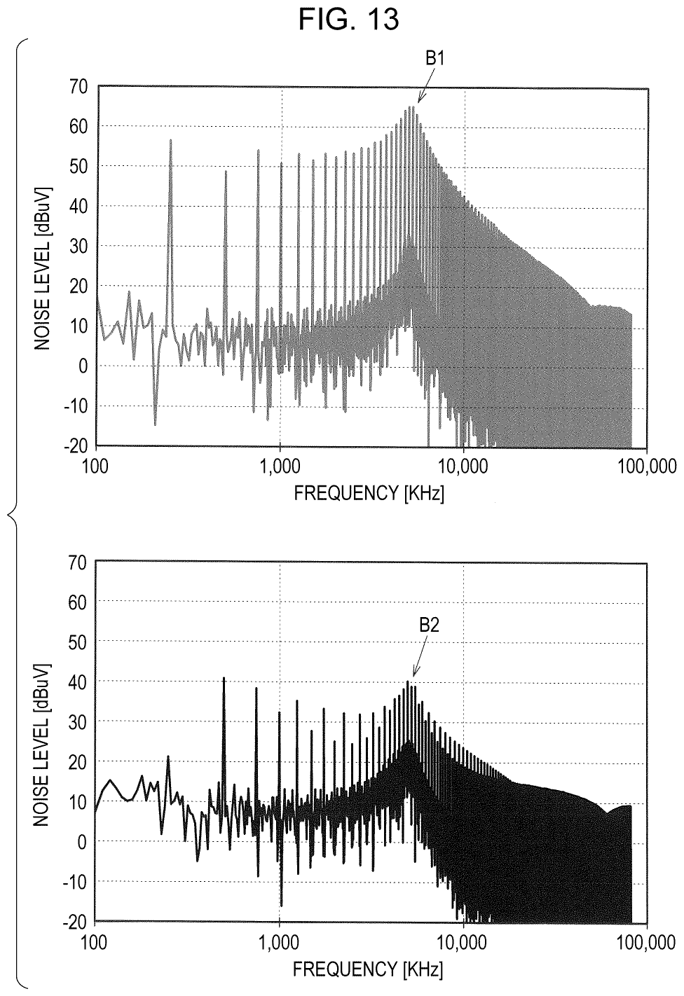

FIG. 13 depicts simulation results of noise characteristics. The upper graph of FIG. 13 depicts noise characteristics in the comparative example, and the lower graph of FIG. 13 depicts noise characteristics in the present embodiment. In the graphs of FIG. 13, the horizontal axis represents the frequency (kHz), and the vertical axis represents the noise level (dBuV). In the comparative example, as indicated by B1, the largest noise level is about 65 dBuV. In contrast, in the present embodiment, as indicated by B2, the largest noise level is about 41 dBuV, showing that the noise level is sufficiently reduced. Therefore, in the present embodiment, the delay times trgl and tfgl are adjusted by the first delay circuit 40 and the second delay circuit 50, enabling the reduction in the noise level, compared to the comparative example where the first delay circuit 40 and the second delay circuit 50 are not provided.

### 4. Other Configurations

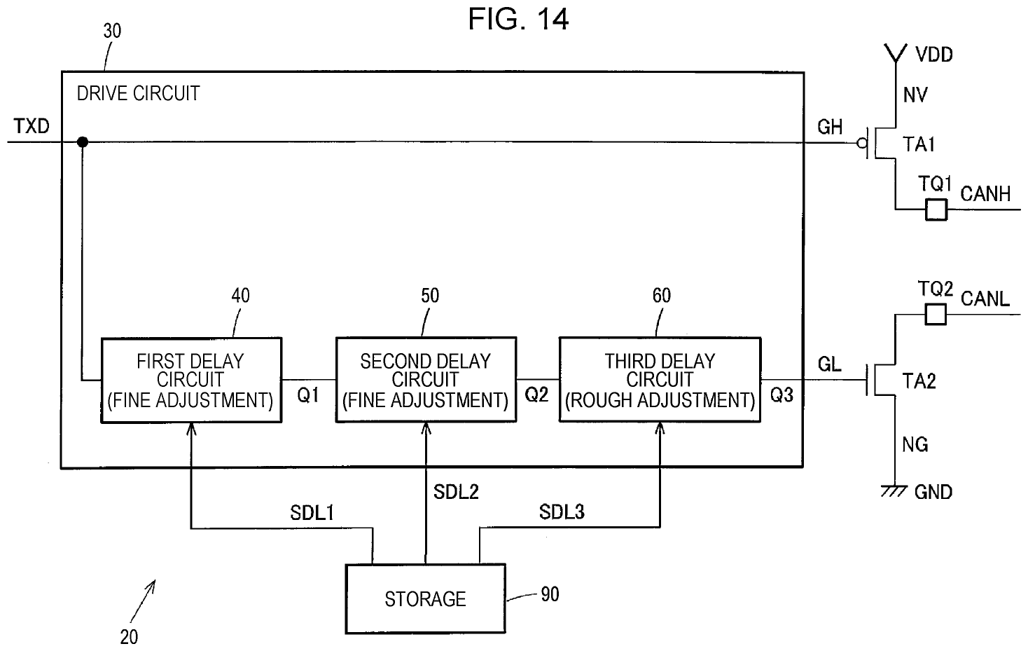

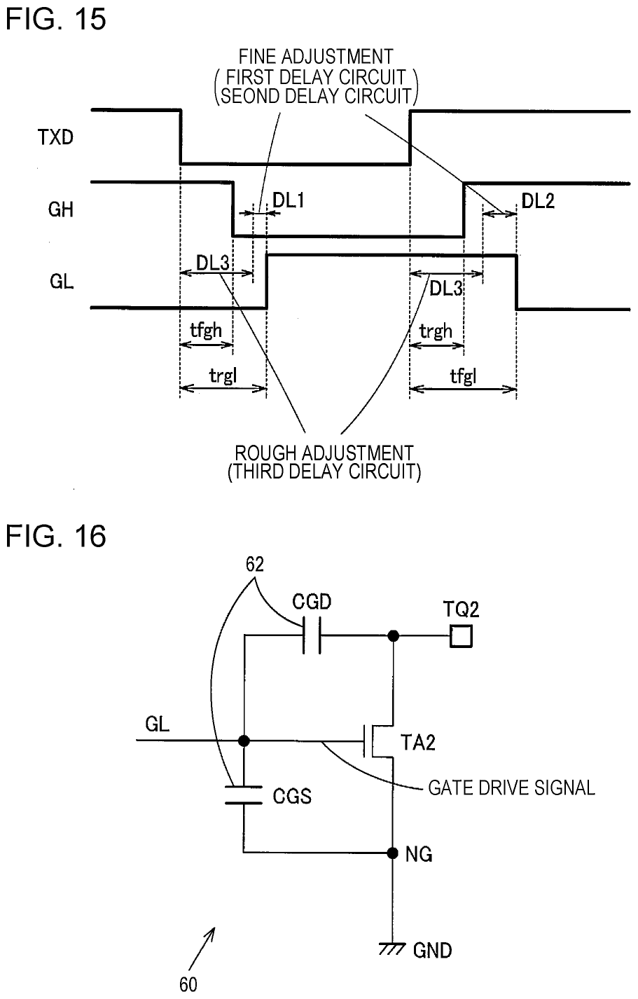

FIG. 14 illustrates another exemplary configuration of the circuit device 20 in the present embodiment. As illustrated in FIG. 14, in addition to the first delay circuit 40 and the second delay circuit 50, a third delay circuit 60 is further included in the drive circuit 30. The third delay circuit 60 sets a third delay time that is the delay time for both the rising edge and the falling edge of the drive signal GL, which is the second drive signal. For instance, the third delay circuit 60 sets a delay time DL3, which is the third delay time as illustrated in FIG. 15 described later, based on delay setting information SDL3 from the storage 90. Specifically, for instance, the delay times trgl and tfgl are finely adjusted by the first delay circuit 40 and the second delay circuit 50 and are roughly adjusted by the third delay circuit 60. For instance, as illustrated in FIG. 14, the signal Q1 from the first delay circuit 40 is input to the subsequent second delay circuit 50, the signal Q2 from the second delay circuit 50 is input to the subsequent third delay circuit 60, and a signal Q3 from the third delay circuit 60 is input as the drive signal GL to the transistor TA2. The arrangement of the first delay circuit 40, the second delay circuit 50, and the third delay circuit 60 is not limited to this and may be modified in various ways in which, for example, the third delay circuit 60 is placed prior to the first delay circuit 40 and the second delay circuit 50.

FIG. 15 illustrates exemplary signal waveforms for explaining operations of the circuit device 20 illustrated in FIG. 14. As illustrated in FIG. 15, the delay time trgl for the rising edge of the drive signal GL is set using the delay time DL3, which is a third delay time, set by the third delay circuit 60 and using the delay time DL1, which is the first delay time, set by the first delay circuit 40. For instance, the delay time trgl is roughly adjusted using the delay time DL3 set by the third delay circuit 60 and is finely adjusted using the delay time DL1 set by the first delay circuit 40. The delay time DL3 used for the rough adjustment is longer than the delay time DL1 used for the fine adjustment. Additionally, the delay time DL1 used for the fine adjustment is adjustable in a higher resolution than the delay time DL3 used for the rough adjustment.

Additionally, as illustrated in FIG. 15, the delay time tfgl for the falling edge of the drive signal GL is set using the delay time DL3, which is the third delay time, set by the third delay circuit 60 and the delay time DL2, which is the second delay time, set by the second delay circuit 50. For instance, the delay time tfgl is roughly adjusted using the delay time DL3 set by the third delay circuit 60 and is finely adjusted using the delay time DL2 set by the second delay circuit 50. The delay time DL3 used for the rough adjustment is longer than the delay time DL2 used for the fine adjustment. Additionally, the delay time DL2 used for the fine adjustment is adjustable in a higher resolution than the delay time DL3 used for the rough adjustment.

Thus, in this configuration example, the drive circuit 30 includes the third delay circuit 60 that sets the third delay time, which is a delay time for both the rising edge and falling edge of the drive signal GL. This configuration enables both the delay time trgl for the rising edge and the delay time tfgl for the falling edge of the drive signal GL to be commonly adjusted by the third delay circuit 60. For instance, the delay time trgl for the rising edge and the delay time tigl for the falling edge may be individually adjusted by the first delay circuit 40 and the second delay circuit 50, and the delay times trgl and tfgl may be adjusted commonly by the third delay circuit 60.

Additionally, the third delay circuit 60 sets the third delay time for a signal for which the first delay time is set by the first delay circuit 40 and the second delay time is set by the second delay circuit 50. For instance, as illustrated in FIG. 15, DL1, which is the first delay time, is set by the first delay circuit 40, and DL3, which is the third delay time, is set by the third delay circuit 60. Additionally, DL2, which is the second delay time, is set by the second delay circuit 50, and DL3, which is the third delay time, is set by the third delay circuit 60. This way enables the delay time trgl for the rising edge of the drive signal GL, for example, to be roughly adjusted using the delay time DL3 of the third delay circuit 60 while being finely adjusted using the delay time DL1 of the first delay circuit 40. This way also enables the delay time tfgl for the falling edge of the drive signal GL, for example, to be roughly adjusted using the delay time DL3 of the third delay circuit 60 while being finely adjusted using the delay time DL2 of the second delay circuit 50.

FIG. 16 illustrates an exemplary configuration of the third delay circuit 60. As illustrated in FIG. 16, the third delay circuit 60 is constituted by a capacitor circuit 62 including a capacitor CGD and a capacitor CGS. For instance, the capacitor CGD is placed between the drain and gate of the transistor TA2. The capacitor CGS is placed between the gate and source of the transistor TA2.

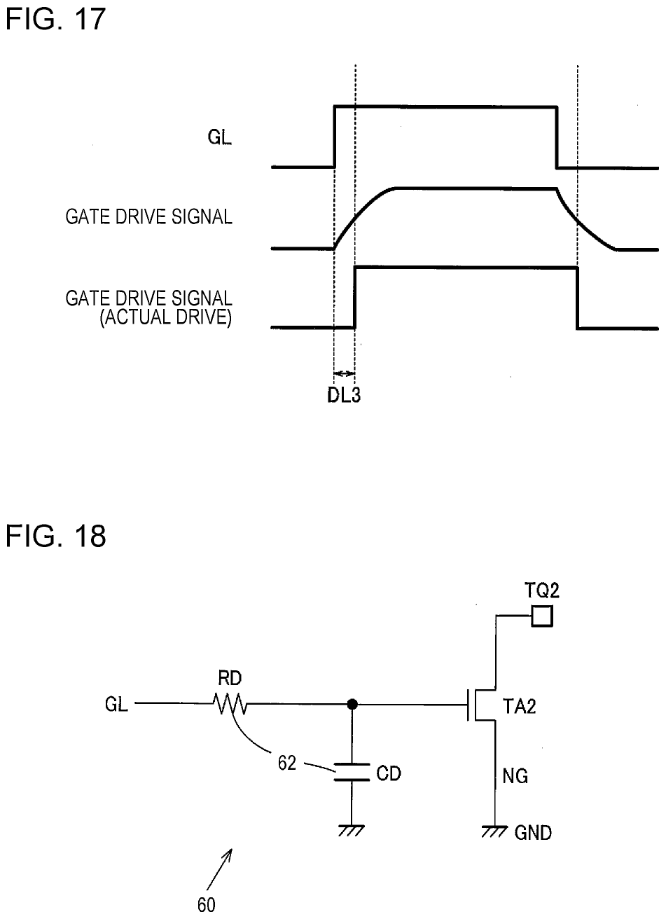

FIG. 17 illustrates exemplary signal waveforms for explaining operations of the third delay circuit 60 illustrated in FIG. 16. The waveform of the drive signal GL is rounded by the capacitor circuit 62 including the capacitors CGD and CGS, and the resultant signal is input as a gate drive signal to the gate of the transistor TA2. Thereby, as illustrated in FIG. 17, the gate of the transistor TA2 is driven by the gate drive signal that is delayed substantially by the delay time DL3.

FIG. 18 illustrates another exemplary configuration of the third delay circuit 60. The third delay circuit 60 illustrated in FIG. 18 is constituted by the capacitor circuit 62 including a capacitor CD and a resistor RD. With the capacitor circuit 62 in this configuration, the gate of the transistor TA2 may be driven by a gate drive signal that is delayed by the delay time DL3 in the same manner as illustrated in FIG. 17.

In such a manner, the third delay circuit 60 includes the capacitor circuit 62 that delays the drive signal GL, which is the second drive signal. In this way, the drive signal GL, the delay time of which is set by rounding the waveform of the drive signal GL by the capacitor of the capacitor circuit 62, may be input to the gate of the transistor TA2.

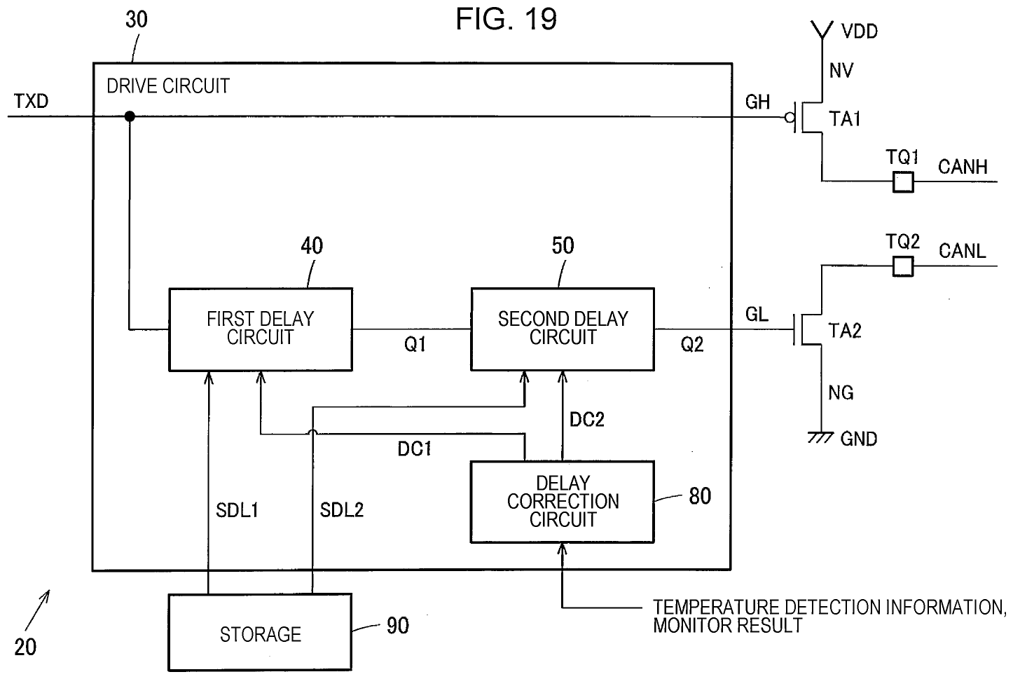

FIG. 19 illustrates another exemplary configuration of the circuit device 20 in the present embodiment. As illustrated in FIG. 19, the drive circuit 30 includes a delay correction circuit 80 that corrects the delay time of the first delay circuit 40 and the delay time of the second delay circuit 50. For instance, as illustrated in FIG. 19, the delay time DL1 of the first delay circuit 40 is set based on the delay setting information SDL1 from the storage 90, and the delay time DL2 of the second delay circuit 50 is set based on the delay setting information SDL2 from the storage 90. The delay correction circuit 80 then corrects the delay times DL1 and DL2 set in this way, for example, by outputting delay correction information DC1 and DC2 to the first delay circuit 40 and the second delay circuit 50, respectively. In this way, in a situation where, with the set delay times DL1 and DL2, it is not possible to appropriately reduce the unbalanced waveforms in the output signals CANH and CANL from the first output terminal TQ1 and the second output terminal TQ2, correction may be performed by the delay correction circuit 80 so that the delay times DL1 and DL2 are changed to appropriate delay times. Therefore, correction may be performed so that the delay times DL1 and DL2 are changed to appropriate delay times in accordance with the situation, enabling the reduction of the unbalanced waveforms in the output signals CANH and CANL to enable the reduction of noise.

Specifically, the delay correction circuit 80 corrects the delay times DL1 and DL2 of the first delay circuit 40 and the second delay circuit 50 based on, for example, temperature detection information or a result of monitoring the output signals CANH and CANL of the high-side transistor TA1 and the low-side transistor TA2. For instance, the delay correction circuit 80 outputs the delay correction information DC1 and DC2, based on temperature detection information from a temperature sensor (not illustrated), to the first delay circuit 40 and the second delay circuit 50, resulting in performing correction so that the delay times DL1 and DL2 are changed to appropriate delay times in accordance with the detected temperature.

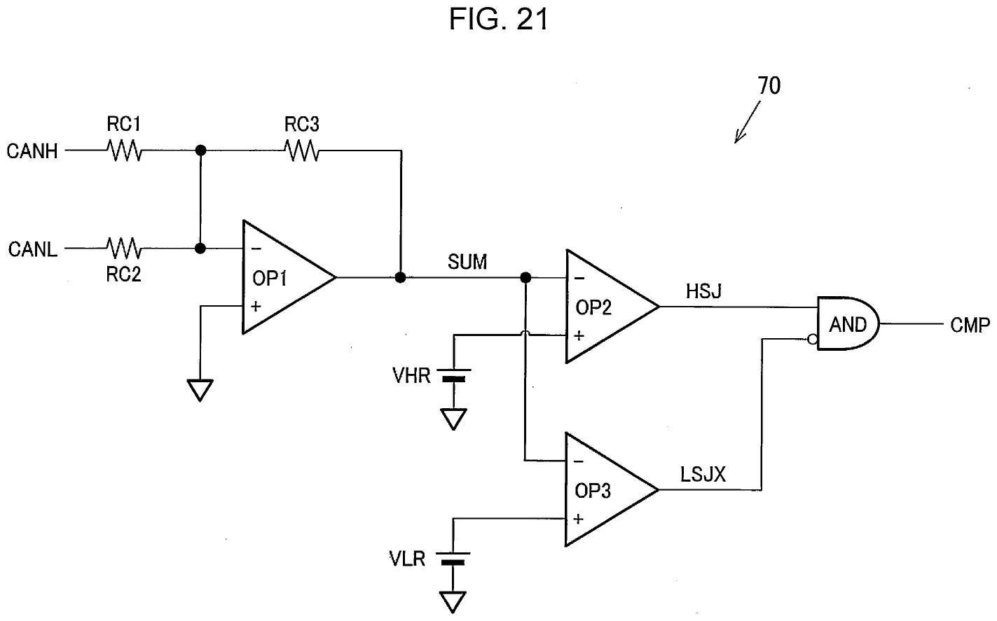

Alternatively, the delay correction circuit 80 outputs the delay correction information DC1 and DC2, based on the result of monitoring the output signals CANH and CANL obtained by a monitor circuit 70 illustrated in FIG. 21 described later, to the first delay circuit 40 and the second delay circuit 50, resulting in performing correction so that the delay times DL1 and DL2 are changed to appropriate delay times according to the monitoring result. For instance, in some cases, as the environment temperature changes, the delay times DL1 and DL2 change from delay times appropriate for noise reduction. Even in such a case, the delay correction circuit 80 may perform correction so that the delay times DL1 and DL2 are changed to appropriate delay times in accordance with the environment temperature. Alternatively, in some cases, when the characteristics and other factors of the transistors TA1 and TA2 change due to, for example, time-dependent changes, the waveforms of the output signals CANH and CANL change, thereby changing the delay times DL1 and DL2 from delay times appropriate for noise reduction. Even in such a case, the delay correction circuit 80 may perform correction so that the delay times DL1 and DL2 are changed to appropriate delay times in accordance with the output signals CANH and CANL.

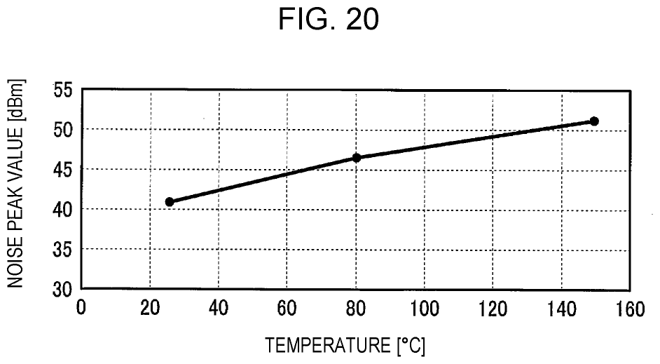

For example, FIG. 20 is a graph depicting the temperature dependence of EMI noise. As depicted in FIG. 20, the peak value of EMI noise is dependent on temperature. In this case as well, the delay correction circuit 80 corrects the delay times DL1 and DL2 of the first delay circuit 40 and the second delay circuit 50 based on temperature detection information, enabling the delay times DL1 and DL2 to be set to values appropriate for noise reduction.

FIG. 21 illustrates an exemplary configuration of the monitor circuit 70 for monitoring the output signals CANH and CANL. The monitor circuit 70 is placed in the circuit device 20.

As illustrated in FIG. 21, the monitor circuit 70 includes operational amplifiers OP1, OP2, and OP3, resistors RC1, RC2, and RC3, and an AND circuit AND. The inverting input terminal (first input terminal) of the operational amplifier OP1 receives output signals CANH and CANL respectively through the resistors RC1 and RC2. The non-inverting input terminal (second input terminal) of the operational amplifier OP1 is set to, for example, the ground. The resistor RC3 is placed between the output terminal and the inverting input terminal of the operational amplifier OP1. Thus, a signal SUM from the operational amplifier OP1 is input to the inverting input terminals of the operational amplifiers OP2 and OP3. The signal SUM is a signal obtained by adding the output signals CANH and CANL, and is a signal corresponding to the sum of the output signals CANH and CANL. A high-potential determination voltage VHR is input to the non-inverting input terminal of the operational amplifier OP2, and a low-potential determination voltage VLR is input to the non-inverting input terminal of the operational amplifier OP3. The AND circuit AND then outputs, as a monitoring result signal CMP, a signal corresponding to the AND of the signal HSJ output from the operational amplifier OP2 and the inverse of the signal LSJX output from the operational amplifier OP3.

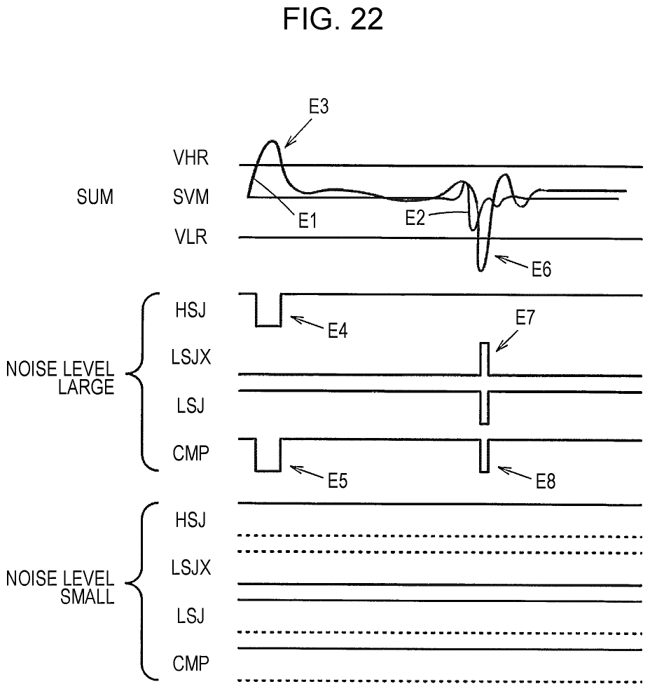

FIG. 22 illustrates exemplary signal waveforms for explaining operations of the monitor circuit 70 illustrated in FIG. 21. E1 indicates exemplary waveforms of the signal SUM when the noise level is high, and E2 indicates exemplary waveforms of the signal SUM when the noise level is low. The signal SUM is a signal corresponding to the sum of the output signals CANH and CANL.

When the noise level is high, in response to the voltage of the signal SUM exceeding the high-potential determination voltage VHR as indicated by E3 in FIG. 22, the signal HSJ changes to the low level, which is the active level, as indicated by E4, and the monitoring result signal CMP changes to the low level, which is the active level, as indicated by E5. Additionally, in response to the voltage of the signal SUM falling below the low-potential determination voltage VLR as indicated by E6, the signal LSJX changes to the high level, which is the active level, as indicated by E7, and the monitoring result signal CMP changes to the low level, which is the active level, as indicated by E8. In contrast, when the noise level is low, the monitoring result signal CMP remains at the high level, which is the non-active level. Thus, with the monitor circuit 70 illustrated in FIG. 21, the noise level of the signal SUM corresponding to the sum of the output signals CANH and CANL may be monitored and be output as the monitoring result signal CMP. The delay correction circuit 80 illustrated in FIG. 19 then receives the monitoring result signal CMP and corrects the delay times DL1 and DL2, enabling the reduction of noise due to the unbalanced waveforms of the output signals CANH and CANL.

As described above, the circuit device in the present embodiment is a circuit device for driving a differential signal bus. The circuit device includes a high-side transistor placed between a power supply node and a first output terminal coupled to the differential signal bus, and a low-side transistor placed between a ground node and a second output terminal coupled to the differential signal bus. The circuit device also includes a drive circuit configured to output a first drive signal to one of a gate of the high-side transistor and a gate of the low-side transistor and to output a second drive signal to another one of the gate of the high-side transistor and the gate of the low-side transistor. The drive circuit includes a first delay circuit configured to set a first delay time that is a delay time for the rising edge of the second drive signal, and a second delay circuit configured to set a second delay time that is a delay time for the falling edge of the second drive signal.

According to the present embodiment, the drive circuit outputs the first drive signal and the second drive signal to one of the high-side transistor and the low-side transistor and to the other. Thereby, the differential signal bus is driven by the high-side transistor, placed between the power supply node and the first output terminal, and the low-side transistor, placed between the ground node and the second output terminal. The first delay time for the rising edge and the second delay time for the falling edge of the second drive signal are independently adjusted by the first delay circuit and the second delay circuit of the drive circuit. In this way, proper adjustment of the first delay time and the second delay time enables the reduction of noise produced by the differential signal bus.

Additionally, in the present embodiment, the first delay circuit may be configured to set the first delay time based on first delay setting information, and the second delay circuit may be configured to set the second delay time based on second delay setting information.

This way enables the first delay time for the rising edge and the second delay time for the falling edge of the second drive signal to be set to any values based on the first delay setting information and the second delay setting information, enabling the reduction of noise produced by the differential signal bus.

Additionally, in the present embodiment, a storage configured to store the first delay setting information and the second delay setting information may be included.

This way enables the first delay circuit and the second delay circuit to set the first delay time for the rising edge of the second drive signal and the second delay time for the falling edge of the second drive signal to appropriate values based on the first delay setting information and the second delay setting information read from the storage.

Additionally, in the present embodiment, the low-side transistor may be an n-type transistor, and the drive circuit may output the second drive signal to the gate of the n-type transistor.

This way enables the first delay circuit and the second delay circuit to set the first delay time for the rising edge and the second delay time for the falling edge of the second drive signal, enabling the reduction of unbalanced waveforms in the output signals from the first output terminal and the second output terminal to reduce noise produced by the differential signal bus.

Additionally, in the present embodiment, the first delay time and the second delay time may differ in length.

This way enables the reduction of unbalanced waveforms in the output signals from the first output terminal and the second output terminal to reduce noise resulting from the unbalanced waveforms.

Additionally, in the present embodiment, the first delay circuit may include a first delay unit configured to delay an input signal to the first delay circuit, and an OR circuit configured to output an OR of the input signal and an output signal from the first delay unit.

This way enables the first delay time of the second drive signal to be set by setting the delay time in the first delay unit of the first delay circuit.

Additionally, in the present embodiment, the second delay circuit may include a second delay unit configured to delay an input signal to the second delay circuit, and an AND circuit configured to output an AND of the input signal and an output signal from the second delay unit.

This way enables the second delay time of the second drive signal to be set by setting the delay time in the second delay unit of the second delay circuit.

Additionally, in the present embodiment, the drive circuit may further include a third delay circuit configured to set a third delay time that is a delay time for both the rising edge and the falling edge of the second drive signal.

This way enables both the first delay time for the rising edge and the second delay time for the falling edge of the second drive signal to be commonly adjusted by the third delay circuit.

Additionally, in the present embodiment, the third delay circuit may be configured to set the third delay time for a signal for which the first delay time is set by the first delay circuit and the second delay time is set by the second delay circuit.

This way enables the first delay time for the rising edge of the second drive signal, for example, to be roughly adjusted using the third delay time of the third delay circuit while being finely adjusted using the delay time of the first delay circuit. This way also enables the second delay time for the falling edge of the second drive signal to be roughly adjusted using the third delay time of the third delay circuit while being finely adjusted using the delay time of the second delay circuit.

Additionally, in the present embodiment, the third delay circuit may include a capacitor circuit configured to delay the second drive signal.

This way enables the second drive signal, the delay time of which is set by rounding the waveform of the second drive signal by the capacitor of the capacitor circuit, to be input to the gate of a transistor.

Additionally, in the present embodiment, the drive circuit may further include a delay correction circuit configured to correct a delay time of the first delay circuit and a delay time of the second delay circuit.

In a situation where, with the set delay times, it is not possible to appropriately reduce the unbalanced waveforms in the output signals from the first output terminal and the second output terminal, this way enables correction to be performed by the delay correction circuit so that the delay time of the first delay circuit and the delay time of the second delay circuit are changed to appropriate delay times.

Additionally, in the present embodiment, the delay correction circuit may be configured to, based on temperature detection information or a result of monitoring output signals of the high-side transistor and the low-side transistor, correct the delay time of the first delay circuit and the delay time of the second delay circuit.

Even when the delay time of the first delay circuit and the delay time of the second delay circuit change from delay times appropriate for noise reduction, this way enables correction to be performed by the delay correction circuit so that the delay time of the first delay circuit and the delay time of the second delay circuit are changed to appropriate delay times in accordance with the output signals.

Although the present embodiment has been described above in details, the person skilled in the art would readily understand that many modifications may be made without substantially departing from new matters and effects of the present disclosure. Accordingly, all of such modifications are considered to fall within the scope of the present disclosure. For example, in the specification or the figures, the terms used at least once together with different broader or synonymous terms may be replaced with the different terms in any part of the specification or the figures. Additionally, all combinations of the present embodiment and modifications are included in the scope of the present disclosure. Additionally, the configuration, operations, and others of the circuit device are not limited to those described in the present embodiment and may be modified in various ways.

What is claimed is:

1. A circuit device for driving a differential signal bus, comprising:
a high-side transistor placed between a power supply node and a first output terminal coupled to the differential signal bus;
a low-side transistor placed between a ground node and a second output terminal coupled to the differential signal bus; and
a drive circuit configured to output a first drive signal to one of a gate of the high-side transistor and a gate of the low-side transistor and to output a second drive signal to another one of the gate of the high-side transistor and the gate of the low-side transistor,
wherein the drive circuit includes:
a first delay circuit configured to set a first delay time that is a delay time for a rising edge of the second drive signal, and
a second delay circuit configured to set a second delay time that is a delay time for a falling edge of the second drive signal.

2. The circuit device according to claim 1, wherein
the first delay circuit is configured to set the first delay time based on first delay setting information, and
the second delay circuit is configured to set the second delay time based on second delay setting information.

3. The circuit device according to claim 2, further comprising:
a storage configured to store the first delay setting information and the second delay setting information.

4. The circuit device according to claim 1, wherein
the low-side transistor is an n-type transistor, and
the drive circuit is configured to output the second drive signal to a gate of the n-type transistor.

5. The circuit device according to claim 1, wherein the first delay time and the second delay time differ in length.

6. The circuit device according to claim 1, wherein the first delay circuit includes
a first delay unit configured to delay an input signal to the first delay circuit; and
an OR circuit configured to output an OR of the input signal and an output signal from the first delay unit.

7. The circuit device according to claim 1, wherein the second delay circuit includes
a second delay unit configured to delay an input signal to the second delay circuit; and
an AND circuit configured to output an AND of the input signal and an output signal from the second delay unit.

8. The circuit device according to claim 1, wherein the drive circuit further includes
a third delay circuit configured to set a third delay time that is a delay time for both the rising edge and the falling edge of the second drive signal.

9. The circuit device according to claim 8, wherein the third delay circuit is configured to set the third delay time for a signal for which the first delay time is set by the first delay circuit and the second delay time is set by the second delay circuit.

10. The circuit device according to claim 8, wherein the third delay circuit includes a capacitor circuit configured to delay the second drive signal.

11. The circuit device according to claim 1, wherein the drive circuit further includes
a delay correction circuit configured to correct a delay time of the first delay circuit and a delay time of the second delay circuit.

12. The circuit device according to claim 11, wherein the delay correction circuit is configured to, based on temperature detection information or a result of monitoring output signals of the high-side transistor and the low-side transistor, correct the delay time of the first delay circuit and the delay time of the second delay circuit.
